(19) United States
(12) Patent Application Publication
(10) Pub. No.: US 2015/0048078 A1
(43) Pub. Date: Feb. 19, 2015

(54) SOLDERING EQUIPMENT FOR CONNECTING SOLAR CELLS

(71) Applicant: Komax Holding AG, Dierikon (CH)

(72) Inventors: Peter Morf, Zürich (CH); Adolf Hofer, Lufingen (CH); Stefan Kaufmann, Aarau (CH)

(21) Appl. No.: 14/454,772

(22) Filed: Aug. 8, 2014

(30) Foreign Application Priority Data
Aug. 14, 2013 (EP) 13180396.7

(51) Int. Cl. B23K 3/08; H01L 31/18; B23K 3/047; B23K 1/002; B23K 1/00

(52) U.S. Cl. CPC B23K 3/087; B23K 1/002; B23K 1/0016; B23K 3/0475; H01L 31/188
USPC 219/616

(57) ABSTRACT

Soldering equipment for connecting solar cells includes an inductor loop for generating a high-frequently magnetic field for soldering conductors to the solar cells and holding-down devices, which devices penetrate the inductor loop, for pressing the conductor onto the conductor tracks of the solar cells. A field-concentrator element of a ferrite material is arranged in each holding-down pin of the holding-down device, whereby the magnetic field can be locally amplified and concentrated.

### FIELD

The invention relates generally to soldering equipment for connecting solar cells. The soldering equipment, which operates on the induction principle, preferably comprises for each conductor track an inductor loop by which a high-frequency magnetic field for soldering a conductor to the solar cells can be generated in a conductor track.

### BACKGROUND

Comparable soldering equipment according to category for the connection of solar cells has become known from WO 2011/012175 A1. The soldering equipment comprises an inductor loop in U-shape, through which holding-down devices for pressing the conductor onto the conductor track of the solar cell are guided. The limbs of the U-shaped inductor loop are formed to be wave-shaped, wherein the holding-down devices respectively penetrate in the region of a widening of the inductor loop. The holding-down devices each consist of a material neutral with respect to magnetic field. In the region of the widenings the inductor loop can consist of a ferrite or be surrounded by a ferrite. In another variant tubular members of ferrite, through each of which a respective holding-down pin can be guided, are mounted on the inductor loop. The ferrites each produce a concentration of the magnetic field. The approaches, which are demonstrated in WO 2011/012175 A1, for concentration of the magnetic field are complicated and consequently comparatively expensive. For special fields of use, for example if there is to be inductive soldering only on very small areas, it can be difficult to achieve this object by this soldering equipment.

### SUMMARY

It is accordingly an object of the present invention to create soldering equipment by which solar cells can be simply and economically connected by inducted soldering. The solder locations produced by the soldering equipment shall satisfy high demands in terms of quality. Moreover, the soldering equipment shall be particularly suitable for soldering on very small surfaces in an optimal and precise manner.

The soldering equipment according to the invention comprises a heat source, which operates on the induction principle, with an inductor loop for generating a high-frequency magnetic field for soldering the conductor to the solar cells. In order to operate the inductor loop the heat source can further comprise a high-frequency generator. A high-frequency current of the high-frequency generator generates a high-frequency magnetic field, which by way of the inductor loop induces in the conductor track and in the electrical conductor arranged along the conductor track eddy currents producing the heat necessary for the soldering process. The soldering equipment further comprises at least one holding-down device, advantageously a plurality of holding-down devices, for pressing the conductor onto the conductor track of the solar cell. The or each holding-down device is in that case constructed as a field concentrator, whereby the magnetic field can be locally amplified and concentrated in the target region in which soldering is to be carried out. Tests with such holding-down devices having field-concentration characteristics have unexpectedly shown that excellent soldering results are achievable. In particular, it is also possible to inductively solder, in a precise manner, locations with very small areas. Use can be made of conventional inductor loops which do not comprise ferrite or are surrounded by ferrite. The arrangement according to the invention is favorable in cost and distinguished by simple construction. Existing items of soldering equipment can be retrofitted in simple manner by replacing the previous holding-down device by the described field-concentrator holding-down device.

The inductor loop can be of U-shaped construction. The limbs of the U can extend on a plane having planoparallelism with respect to the solar cell surfaces. The limbs can be formed to be wave-shaped analogously to WO 2001/012175 A1. In order to form the wave shape the inductor loop can have narrowings and widenings by which development of heat in the solder zones can be further optimized. Each widening can offer access to a soldering location for a holding-down device.

The holding-down device could be an active field concentrator with at least one magnetic coil. The magnetic coil could in this case be oriented in such a manner that the field lines of the active field concentrator and the inductor loop approximately have the same direction. However, for preference the at least one holding-down device is constructed as a passive field concentrator and consists at least partly of a ferrite or another material with high magnetic permeability or the holding-down device includes such a material.

It can be particularly preferred if the at least one holding-down device comprises at least one holding-down pin which consists of a ferrite or another material with high magnetic permeability. This holding-down device ferrite pin can have, for example, a cylindrical outer contour. The free end of the holding-down pin, which faces the solar cell, can have a support surface for acting on the conductor to press the conductor onto the conductor track of the solar cell. Such ferrite pins are available cheaply and can be produced simply.

It can be advantageous if the at least one holding-down device comprises a holding-down pin with a tubular base body, wherein a field-concentrator element of a ferrite or another material with high magnetic permeability is arranged in the cavity of the base body in the front end of the base body facing the solar cell. The field-concentrator element can, for example, be glued or clamped in place in the interior of the base body. Other possibilities of fastening are obviously also conceivable. The tubular base body can have characteristics which are neutral with respect to magnetic field and can consist of glass, ceramic materials or a plastics material.

It can be advantageous for specific fields of use if the tubular body is designed to be open in the region of the front end. The field-concentrator element can be positioned to be flush with the free end of the tube. However, it would also be conceivable for the field-concentrator element to be arranged to be set back relative to the front, free end of the tubular base body, as a consequence of which the field-concentrator element cannot directly contact the conductor.

Alternatively, the tubular base body can be closed at least in the region of the front end. In this way it can be ensured that the field-concentrator element arranged in the base body does not directly contact the conductor to be soldered.

The holding-down device can comprise a tubular base body with base, which is monolithically formed at the base body, for closing the front end of the base body. Alternatively, a foot part, which forms a support surface acting on the conductor during the pressing process, can be fastened to the front end of the base body facing the solder cell. The foot part can be widened for increasing the support area relative to the base body. If the base body is of cylindrical form, it can be advantageous if the foot part predetermines a circular support area having a circle diameter greater than the cylinder diameter of the base body.

Moreover, it can be advantageous if the at least one holding-down device penetrates the inductor loop. The inductor loop is preferably made of a metallic material. The inductor loop does not have to have field-concentration characteristics. An arrangement of that kind is favorable in cost, wherein at the same time good soldering results are achievable.

It is particularly preferred if the soldering equipment comprises a plurality of the afore-described holding-down devices. The several holding-down devices, which are preferably arranged adjacent to one another in a row, can act in common to press an already deposited conductor track onto the solar cell. Due to the fact that the holding-down devices simultaneously press the conductor track over the entire length a simple and reliable production method results. In addition, production quality can be further increased.

The at least one holding-down device can be mounted in the soldering equipment to be resilient in vertical direction, whereby gentle handling of the solar cell can be ensured. If the soldering equipment comprises a cassette or other housing for holding the holding-down device it can be particularly advantageous if the holding-down device or devices is or are mounted to be resilient with respect to the lowering direction extending in vertical direction. However, other resilient mountings of the holding-down device would also be conceivable. If, for example—as has just been explained—the holding-down device comprises a holding-down pin and a tubular base body it can be advantageous if the holding-down pin is resiliently mounted in the tubular base body.

With respect to method the invention is distinguished by the fact that use is made of holding-down devices, which are constructed as field concentrators and by which the high-frequency magnetic field produced preferably by means of a high-frequency generator and an inductor loop is locally amplified and concentrated. This soldering method for connecting solar cells is distinguished inter alia by the fact that small soldering locations can be produced with high precision.

### DESCRIPTION OF THE DRAWINGS

Further individual features and advantages are evident from the following description and embodiments and from the drawings, in which:

FIG. 1 shows a perspective illustration of an inductor loop with holding-down devices of soldering equipment according to the invention for the connection of solar cells.

FIG. 2 shows a simplified perspective illustration of an alternative inductor loop with holding-down devices for soldering equipment.

FIG. 3 shows one of the holding-down devices of FIG. 2 in another perspective illustration.

FIG. 4 shows a longitudinal section through a holding-down device, which penetrates an inductor loop.

FIG. 5 shows an alternative form of the holding-down device according to FIG. 4.

FIG. 6 shows a third embodiment for a holding-down device.

FIG. 7 shows a holding-down device according to a fourth embodiment.

### DETAILED DESCRIPTION

The following detailed description and appended drawings describe and illustrate various exemplary embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

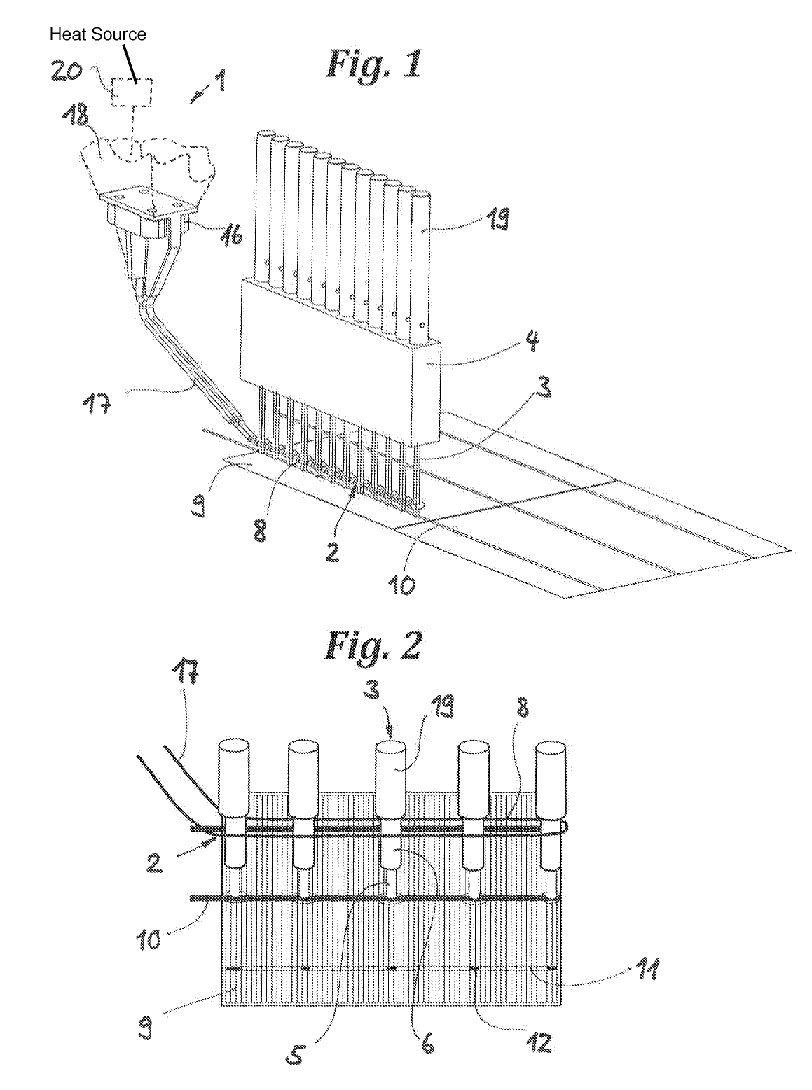

FIG. 1 shows soldering equipment, which is denoted in general by 1, for the connection of solar cells, in which use is made of electromagnetic induction effect for heat generation for soldering the electrical conductors 10 to the solar cells. The soldering equipment 1 comprises a heat source operating on the induction principle. The heat source comprises a high-frequency generator, which is indicated schematically in FIG. 1 by 20. The high-frequency generator 20 is connected with a soldering head, which is indicated by 18 and at which the inductor loop, which is denoted by 2, for generating a high-frequency magnetic field for the soldering process is arranged. This heat source, which operates on the induction principle and which by means of the high-frequency generator 20 generates a high-frequency current with, for example, a frequency of 800 kHz to 900 kHz in the inductor loop, produces a high-frequency magnetic field. The solar cells 9 can be electrically connected together by the soldering equipment 1, in which case electrical conductors 10 (for example small copper strips) are soldered to the conductor tracks at the upper sides of the solar cells.

In the illustration according to FIG. 1 the solar cells each have, by way of example, three parallel conductor tracks. Correspondingly, adjacent solar cells 9 are connected with the use of three conductors. For the sake of simplicity and for better understanding merely one inductor loop 2 is illustrated in FIG. 1. The soldering equipment 1 itself comprises two further (not illustrated) inductor loops, which can be arranged at the soldering head 18. The three conductor tracks can thus be soldered simultaneously over the entire cell length thereof by the soldering head 18 by means of three inductor loops 2. However, other loop arrangements would also be conceivable in principle. Instead of providing a respective inductor loop per conductor track, it would, for example, obviously also be possible to electrically connect solar cells by a single, but transversely displaceable, inductor loop.

The inductor loop 2 comprises a connecting member 16 fastened or fastenable to the soldering head 18, a connecting member 17 connected therewith and a U-shaped limb section 8. The connecting member 16 serves as a support for the inductor loop 2 and comprises the water connection, the electrical connection and the high-frequency generator for generating the high-frequency current in the inductor loop 2. The limb section 8 is spaced from the upper side of the solar cell 9 and extends along the conductor tracks of the solar cells. The limbs, which are formed by tubes, of the limb section 8 are, as evident, formed to be wave-shaped, as a result of which narrowings and widenings are formed. The inductor loop 2 is penetrated in the region of the widenings by holding-down devices 3 by which the conductor 10 is pressed onto the conductor track of the solar cell 9. The reference numeral 4 denotes a case for mounting the holding-down device and 19 denotes weights for pressing on the holding-down device. Apart from the special design of the holding-down device 3, which is shown and explained in detail in the following, soldering equipment of that kind or similar soldering equipment—apart from the holding-down device described in detail in the following—are already known as such to the expert. For example, mention may be made of WO 2011/012175 A1, which hereby expressly is incorporated by reference as part of the disclosure of this application. Accordingly, reference is made to the afore-mentioned document with respect to further constructional details for the soldering equipment.

In FIG. 2 the holding-down pins 5 act on the conductor 10 associated with the middle conductor track. No conductor has been placed on the front conductor track denoted by 11. The contact zones, which are to be subsequently soldered, are denoted by 12.

As evident from FIG. 2, the inductor loop 2 does not necessarily have to be of wave-shaped form and have narrowings and widenings. In the present example, the limbs, which are arranged above the conductor 10, of the U-shaped limb section 8 are formed to be straight. FIG. 2 shows an inductor loop 2 with a plurality of holding-down devices 3 penetrating the loop. The holding-down devices 3 comprise holding-down pins 5 which press the conductor 10 onto the associated conductor track of the solar cell 9. By contrast to the holding-down devices which are known from the prior art and which through pressing serve only for positional fixing of the conductors on the solar cells before and during the soldering process, the holding-down devices 3 according to the invention have an additional function. The holding-down devices 3 not only prevent unintended slipping of the deposited conductors 10, but also participate in the inductive soldering process, since the holding-down devices 3 are constructed as field concentrators. Each holding-down device 3 is constructed as a passive field concentrator and consists at least partly of a ferrite or another material with high magnetic permeability. The guide sleeves can be fixedly mounted in a housing (not illustrated here), for example, the case 4 shown in FIG. 1. However, it is also conceivable to provide a resilient mounting of the holding-down devices in the housing 4 for movement in a vertical direction. The soldering process begins with the soldering head being lowered together with the mentioned housing from an upper position to a soldering position. Before this position is reached the holding-down devices already come into contact with the contact strips and press these onto the solar cells. This takes place due to the weight force of the holding-down devices 3 with the weights 19. The holding-down devices 3 are mounted in the guide sleeves 6 to be freely movable in vertical direction, in which case it is ensured, thanks to a shoulder at the weights, that dropping out of the housing is not possible. Obviously, it would also be conceivable for the holding-down devices to be actively lowered (for example by means of pneumatic cylinders). The guide sleeves do not have to have field-concentration characteristics. However, in addition to the holding-down pins designed as field concentrators, the guide sleeves could also consist of ferrite.

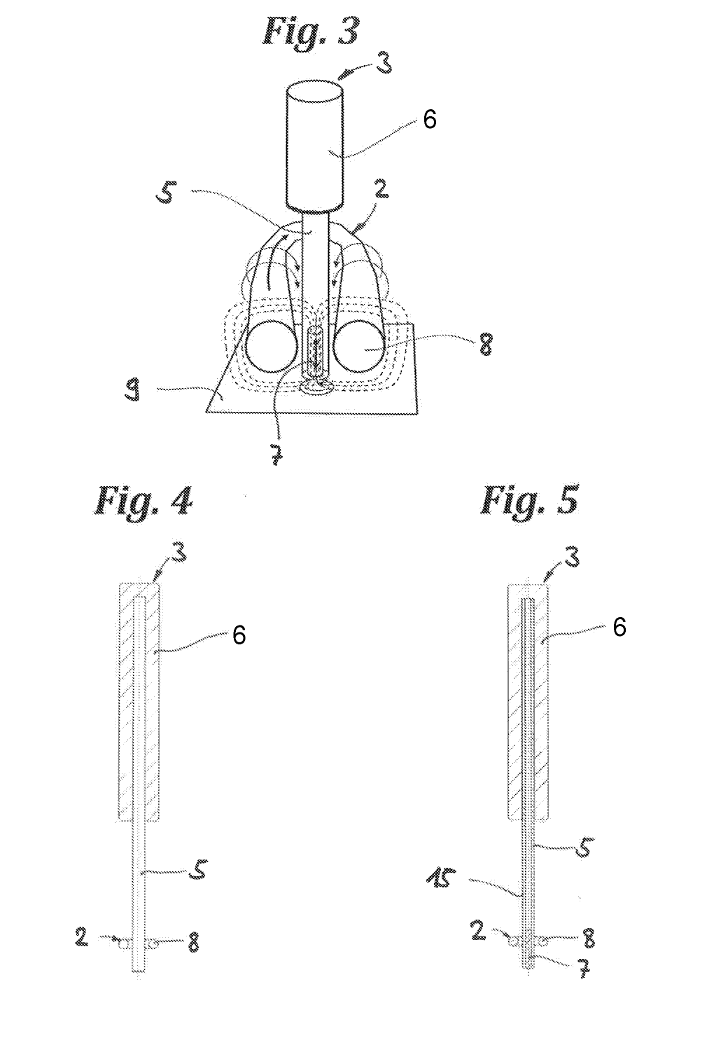

The mode of operation of the holding-down device 3 constructed as a field concentrator is evident from FIG. 3. The high-frequency magnetic field generated by the inductor loop 2 is indicated by semicircular arrows oriented in opposite sense. A field-concentrator element 7, for example of ferrite, is arranged in the holding-down pin 5. The field lines around the field concentrator are indicated by dashed lines. As is apparent, thanks to the field-concentrator element 7 a local amplification and concentration of the magnetic field results. Development of heat is thus restricted to a comparatively small area. The soldering process, which is performable by the soldering equipment, for connecting solar cells is thus distinguished, as is apparent, by the fact that small soldering locations can be produced with high precision.

FIG. 4 shows a holding-down device 3 with a holding-down pin 5 carried by a guide sleeve 6, wherein the holding-down pin 5 is made of a ferrite. However, it would obviously also be possible to produce the holding-down pin from another material with high magnetic permeability.

FIGS. 5 to 7 show variants in which the holding-down pin 5, which, for example, is mounted or guided to be movable in vertical direction in a guide sleeve (not illustrated) associated with a housing of the soldering equipment, is of two-part or multi-part construction. Instead of constructing the entire holding-down pin as a field concentrator, in the holding-down pins according to FIGS. 5 to 7 a separate element 7 is arranged, which consists of a material with high magnetic permeability (for example ferrite). This element, which is termed field-concentrator element in the following, is arranged in the region of the front ends of the holding-down pins.

In FIG. 5 the holding-down pin 5 consists of a tubular base body 15 in which a field-concentrator element 7 is arranged. The base body 15 is a cylindrical tube consisting of, for example, glass, ceramic or a plastics material. The tube 15 is in itself therefore neutral with respect to magnetic field. The field-concentrator element 7 of a ferrite is arranged in the front, open end, which faces the solar cell, of the tubular base body 15. The field-concentrator element can, for example, be glued or clamped in place in the interior of the base body 15.

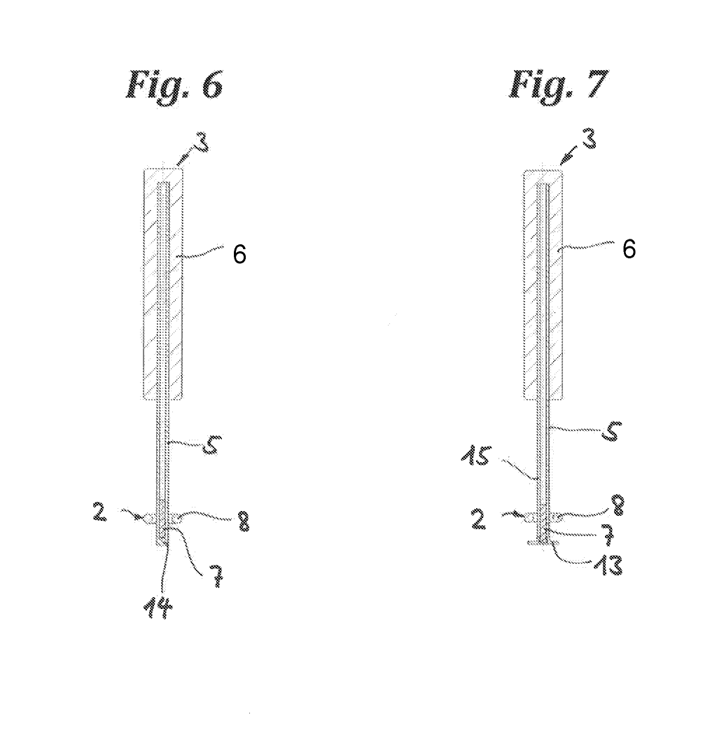

In the embodiment according to FIG. 6 the base body for the holding-down pin 5 is closed in the region of the free end. A base 14 is connected at the front with the tubular section. It is thus ensured that the field-concentrator element 7 cannot directly contact the conductor. Instead of a base formed at the tube, the holding-down pin 5 can also be equipped with a separate component which closures the tubular section.

In FIG. 7 a foot part 13 is fastened to the tubular base body 15. The foot part 13, which is widened relative to the base body 15, thus forms an enlarged support area which acts on the conductor during the pressing process.

In accordance with the provisions of the patent statutes, the present invention has been described in what is considered to represent its preferred embodiment. However, it should be noted that the invention can be practiced otherwise than as specifically illustrated and described without departing from its spirit or scope.

What is claimed is:

1. Soldering equipment for connecting solar cells, comprising:
an induction heat source for soldering an electrical conductor to a conductor track on the solar cells, wherein the heat source includes an inductor loop for generating a high-frequency magnetic field for soldering the conductor; and
at least one holding-down device for pressing the conductor onto the conductor track, wherein the at least one holding-down device is formed as a field concentrator, whereby the magnetic field is locally amplified and concentrated.

2. The soldering equipment according to claim 1 wherein the at least one holding-down device is formed at least partly of or contains a ferrite material or another material with high magnetic permeability.

3. The soldering equipment according to claim 1 wherein the at least one holding-down device includes a holding-down pin formed of the ferrite material or the another material with high magnetic permeability.

4. The soldering equipment according to claim 1 wherein the at least one holding-down device includes a holding-down pin with a tubular base body, wherein a field-concentrator element formed of a ferrite material or another material with high magnetic permeability is arranged in a cavity of the base body in a front end of the base body facing the solar cells.

5. The soldering equipment according to claim 4 wherein the tubular base body is formed open at the front end.

6. The soldering equipment according to claim 4 wherein the tubular base body is closed at the front end.

7. The soldering equipment according to claim 6 wherein the tubular base body has in integral base formed at and closing the front end, or a foot part is fastened to the base body to close the front end, the foot part being wider than the base body to increase a support area.

8. The soldering equipment according to claim 1 wherein the at least one holding-down device penetrates the inductor loop.

9. The soldering equipment according to claim 1 including a plurality of the at least one holding-down device for pressing the conductor onto the conductor track of the solar cells.

10. The soldering equipment according to claim 1 wherein the at least one holding-down device is resiliently mounted in the soldering equipment for movement in a vertical direction.

11. The soldering equipment according to claim 1 including a case mounting the at least one holding-down device, the at least one holding-down device being resiliently mounted with respect to a lowering direction extending in a vertical direction.
